(19) United States
(12) Patent Application Publication
(10) Pub. No.: US 2025/0317134 A1
(43) Pub. Date: Oct. 9, 2025

(54) WINDING DRIVER CIRCUITRY WITH REDUCED COMMUTATION LOOP

(71) Applicant: Infineon Technologies Austria AG, Villach (AT)

(72) Inventors: Volodymyr YAKOBNIUK, VILLACH (AT); Urban MEDIC, Logatec (SI)

(73) Assignee: Infineon Technologies Austria AG, Villach (AT)

(21) Appl. No.: 18/630,080

(22) Filed: Apr. 9, 2024

(51) Int. Cl. H03K 17/06; H01L 23/367

(52) U.S. Cl. CPC H03K 17/063; H01L 23/367; H03K 2217/0063; H03K 2217/0072

(57) ABSTRACT

One example in this disclosure includes a winding driver assembly comprising: a substrate; a first switch affixed to a first surface of the substrate; a second switch affixed to a second surface of the substrate, the first switch and the second switch connected in series via a first circuit path extending through the substrate; and a capacitor disposed in series in a second circuit path extending through the substrate, the first switch and the second switch connected in series via the second circuit path. The placement of the component such as first switch, second switch, first circuit path, second circuit path, etc., discussed herein uses a respective inductive loop associated with the winding driver assembly.

### BACKGROUND

A conventional printed circuit board (PCB) or printed wiring board is a laminated structure of conductive layers separated by insulating layers. In general, PCBs have two functions. The first is to secure electronic components at designated locations on the outer layers by means of soldering. The electronic circuit instantiated by the populated circuit board is designed to provide one or more specific functions. After fabrication, the electronic circuit is powered to perform the desired functions.

One use of a conventional printed circuit board and corresponding circuitry is to control current through respective one or more windings of a motor. For example, the motor may include a first winding, a second winding, and a third winding. Conventional winding driver circuitry on the printed circuit board can be configured to include a first winding driver to control first current through the first winding, a second winding driver to control second current through the second winding, and a third winding driver to control third current through the third winding. Control of the currents through the multiple windings causes a rotor of the motor to turn, providing a desired mechanical function.

### BRIEF DESCRIPTION

Implementation of clean energy (or green technology) is very important to reduce our impact as humans on the environment. In general, clean energy includes any evolving methods and materials to reduce an overall toxicity of energy consumption on the environment.

This disclosure includes the observation that raw energy, such as received from green energy sources or non-green energy sources, can be used to perform a desired function such as control operation of a respective motor. Regardless of whether energy is received from green energy sources or non-green energy sources, it is desirable to make most efficient use of raw energy provided by such systems to reduce our impact on the environment. This disclosure contributes to reducing our carbon footprint (and green energy) via more efficient energy usage and circuit implementations supporting same. Additionally, this disclosure is directed to providing better performance of controlling a respective motor via novel winding driver circuitry layout.

For example, as discussed herein, a fabricator produces one or more assemblies via unique placement of circuit components to provide a smaller commutation loop, resulting in higher performance control of a respective motor.

More specifically, this disclosure includes one or more apparatus, systems, methods, etc. An apparatus can be configured to include a substrate, a first switch, a second switch, and a capacitor. The first switch may be affixed to a first surface of the substrate. The second switch may be affixed to a second surface of the substrate. The second surface may be disposed opposite the first surface of the substrate. Further, the first switch and the second switch may be connected in series via a first circuit path extending through the substrate. The capacitor may be disposed in series in a second circuit path extending through the substrate. The first switch and the second switch may be connected in series in or via the second circuit path.

In further examples as discussed herein, a series combination of the first circuit path, the first switch, the second circuit path, and second switch may create an inductive circuit loop (a.k.a., commutation loop) during certain conditions of operating the respective first switch and the second switch. Placement and novel connectivity of the components including the first switch, the second switch, and the capacitor (as well as corresponding series connections) as discussed herein provide a reduced size commutation loop.

In accordance with one example, the first circuit path may be connected between a first node of the first switch and a first node of the second switch; the second circuit path may be connected between a second node of the first switch and a second node of the second switch. A first portion of the second circuit path may be disposed between a first portion of the substrate and the first switch; a second portion of the second circuit path may be disposed between the first portion of the substrate and the second switch.

Yet further, the first node of the first switch may be a source node; the first node of the second switch may be a drain node.

Still further, the apparatus as discussed herein can be configured to include a controller operative to control switching operation of the first switch and the second switch. The controlled switching operation may control a flow of current from the first circuit path through a winding of a motor.

In one example, the capacitor may be disposed in any suitable location such as nearer the first node of the first switch than the second node of the first switch to reduce a size of the commutation loop.

The apparatus as discussed herein may further include a first heat sink and a second heat sink. The first heat sink may be in physical or thermal contact with the first switch; the second heat sink may be in physical or thermal contact with the second switch. An assembly of the first switch, the substrate, and the second switch may be disposed between the first heat sink and the second heat sink.

Yet further, the apparatus as discussed herein can be configured to include a first temperature sensor and a second temperature sensor. The first temperature sensor may be disposed in a first cavity of the substrate between the first switch and the second switch; the second temperature sensor may be disposed in a second cavity of the substrate between the first switch and the second switch.

The first temperature sensor can be configured to measure a temperature of the first switch. The second temperature sensor can be configured to measure a temperature of the second switch.

In yet another example, the first circuit path may provide connectivity between a first node of the first switch and a first node of the second switch; a first portion of the second circuit path may be configured to convey a first voltage to a first node of the capacitor and a second node of the first switch; and a second portion of the second circuit path may be configured to convey a second voltage to a second node of the capacitor and a second node of the second switch. The second voltage may be a second voltage with respect to the first voltage. The apparatus may further include a controller operative to control operation of the first switch and the second switch to convert the first voltage and the second voltage into an appropriate output current outputted from the first circuit path to a first winding of a motor.

In accordance with another example discussed herein, the first circuit path can be configured to provide connectivity between a first node of the first switch and a first node of the second switch. The second circuit path may include a first portion, a second portion, and a third portion. The first portion of the second circuit path can be configured to extend from a second node of the first switch to the second portion of the second circuit path; the second portion of the second circuit path may extend from the first surface through the substrate to the second surface of the substrate to the third portion; the third portion of the second circuit path may extend on the second surface from the second portion to the second node of the second switch.

Additionally, the first portion of the second circuit path may be disposed between the substrate and the first switch; the third portion of the second circuit path may be disposed between the substrate and the second switch.

In one example, the substrate may be disposed between the first switch and the second switch.

In another example as discussed herein, a first portion of the second circuit path may extend adjacent to the first switch; a second portion of the second circuit path may extend adjacent to the second switch; and at least a portion of the substrate may be disposed between the first portion of the second circuit path and the second portion of the second circuit path.

Still further, the second circuit path may be configured to support conveyance of temporary current flow during a transition of switching between a first mode and a second mode; the first mode can be configured to include activation of the first switch and deactivation of the second switch; the second mode can be configured to include deactivation of the first switch and an inherent diode in the second switch operating in a forward bias state.

In another example, an apparatus as discussed herein may include a substrate, a first switch, a second switch, and a capacitor. The first switch may be affixed to a first surface of the substrate; the second switch may be affixed to the first surface of the substrate as well. The first switch and the second switch may be connected in series via a first circuit path connecting a first node of the first switch to a first node of the second switch. The capacitor may be disposed in series in a second circuit path extending from a second node of the first switch to a second node of the second switch.

In one example as discussed herein, at least a first portion of the second circuit path may reside between the first switch and the substrate; at least a second portion of the second circuit path may reside between the second switch and the substrate. A series combination of the first circuit path, the first switch, the second circuit path, and the second switch may create an inductive circuit loop (a.k.a., commutation loop).

Yet another apparatus as discussed herein can be configured to include a substrate, a first switch affixed to the substrate, and a first temperature sensor. The first temperature sensor may be disposed in a first cavity of the substrate between the first switch and a first portion of the substrate. The first temperature sensor can be configured to measure a temperature of the first switch.

Yet further, the apparatus as discussed herein can be configured to include a second switch affixed to the substrate. The second temperature sensor may be disposed in a second cavity of the substrate between the second switch and a second portion of the substrate. The second temperature sensor can be configured to measure a temperature of the second switch.

In still further examples, the first switch may be affixed to a first surface of the substrate; the second switch may be affixed to a second surface of the substrate. The second surface can be configured to face an opposite direction with respect to the first surface.

In another example as discussed herein, the first cavity can be configured to include a first contact element and a second contact element. The first temperature sensor can be configured to include a first node coupled to the first contact element of the first cavity. The first temperature sensor can be configured to include a second node coupled to the second contact element of the first cavity.

The second cavity may include a first contact element and a second contact element as well. The second temperature sensor can be configured to include a first node coupled to the first contact element of the second cavity. The second temperature sensor can be configured to include a second node coupled to the second contact element of the second cavity.

Note that this disclosure includes useful techniques. For example, in contrast to conventional techniques, the novel circuit as discussed herein provides a way to fabricate an inductive load driver circuit having a small sized commutation loop. The reduced sized commutation loop ensures that magnetic energy passing through the commutation loop does not undesirably impact the desired flow of current to a respective winding (a.k.a., inductive load).

Note further that any of the resources as discussed herein can include one or more computerized devices, apparatus, hardware, etc., execute and/or support any or all of the method operations disclosed herein. In other words, one or more computerized devices or processors can be programmed and/or configured to operate as explained herein to carry out the different techniques as described herein.

Other aspects of the present disclosure include software programs and/or respective hardware to perform any of the operations summarized above and disclosed in detail below.

Additionally, note that although each of the different features, techniques, configurations, etc., herein may be discussed in different places of this disclosure, it is intended, where suitable, that each of the concepts can optionally be executed independently of each other or in combination with each other. Accordingly, the one or more present inventions as described herein can be embodied and viewed in many different ways.

Also, note that this preliminary discussion of techniques herein (BRIEF DESCRIPTION) purposefully does not specify every novel aspect of the present disclosure or claimed invention(s). Instead, this brief description only presents general aspects and corresponding points of novelty over conventional techniques. For additional details and/or possible perspectives (permutations) of the invention(s), the reader is directed to the Detailed Description section (which is a summary) and corresponding figures of the present disclosure as further discussed below.

### BRIEF DESCRIPTION OF THE DRAWINGS

FIG. 1 is an example diagram illustrating a motor driver circuit as discussed herein.

FIG. 2A is an example diagram illustrating operation of a respective winding driver in a first mode as discussed herein.

FIG. 2B is an example diagram illustrating a second mode of initial transitioning from the activation of the high-side switch to operation in the freewheeling mode as discussed herein.

FIG. 2C is an example diagram illustrating a third mode of transitioning from the activation of the high-side switch to operation in the freewheeling mode as discussed herein.

FIG. 2D is an example diagram illustrating a fourth mode of operating respective switch circuitry in a freewheeling mode as discussed herein.

FIG. 3 is an example side view diagram of a respective winding driver circuit providing reduced inductance (reduced cross-section) associated with a commutation loop as discussed herein.

FIG. 4 is an example diagram illustrating reduced cross-section area of a commutation loop as discussed herein.

FIG. 5 is an example diagram illustrating implementation of a respective winding driver circuit and corresponding heat sinks as discussed herein.

FIG. 6 is an example diagram illustrating implementation of a winding driver circuit including multiple switches disposed on different surfaces of a circuit board substrate as discussed herein. Note that FIG. 6 is similar to FIG. 4, but with multiple layers of a printed circuit board being used for the circuit paths.

FIG. 7 is an example diagram illustrating implementation of a winding driver circuit including a first switch and a second switch disposed on a same surface of a circuit board substrate as discussed herein.

FIG. 8 is an example diagram illustrating implementation of multiple temperature sensor devices to monitor a respective temperatures of switches in a winding driver circuit as discussed herein.

FIG. 9 is an example diagram illustrating implementation of a respective temperature sensor and cavity of a circuit board as discussed herein.

The foregoing and other objects, features, and advantages of the disclosed matter herein will be apparent from the following more particular description herein, as illustrated in the accompanying drawings in which like reference characters refer to the same parts throughout the different views. The drawings are not necessarily to scale, with emphasis instead being placed upon illustrating the principles, concepts, aspects, techniques, etc.

### DETAILED DESCRIPTION

The system improvements shown in this disclosure are based on the top-side cooled MOSFET package which makes it possible to utilize the electrical benefits of the multilayer layout versatility, while achieving comparable thermal characteristics of state-of-the-art SMD packages on IMS boards. This is made possible due to the separated thermal path via thermal pad on top of the package so the board does not influence the heat conduction from the MOSFETs. The electrical layout can thus include more complex features improving the system electrical performance.

One such feature as discussed herein is the compensation of the loop inductance of the half bridge via a dedicated capacitor/capacitors placed or arranged and connected in a specific location on the board so as to reduce the effect of the parasitic inductance of the half bridge loop.

One aspect of the board layout of a half bridge, is reducing the inevitable parasitic inductance inherent to the loop formed between the two half bridge transistors (such as Q1 and Q2), the corresponding decoupling capacitor and the interconnections between them—the so called loop inductance of the half bridge. The loop inductance contributes to voltage and current overshoots supplied to a respective motor winding during switching of the half bridge from one mode to another. If present, the overshoots in effect are cause for margins in component breakdown voltages, meaning that voltage ratings of components used need to be higher than supply voltage. The margin increases with the overshoot amplitude. Using transistors with smaller threshold voltages means conduction properties are generally better.

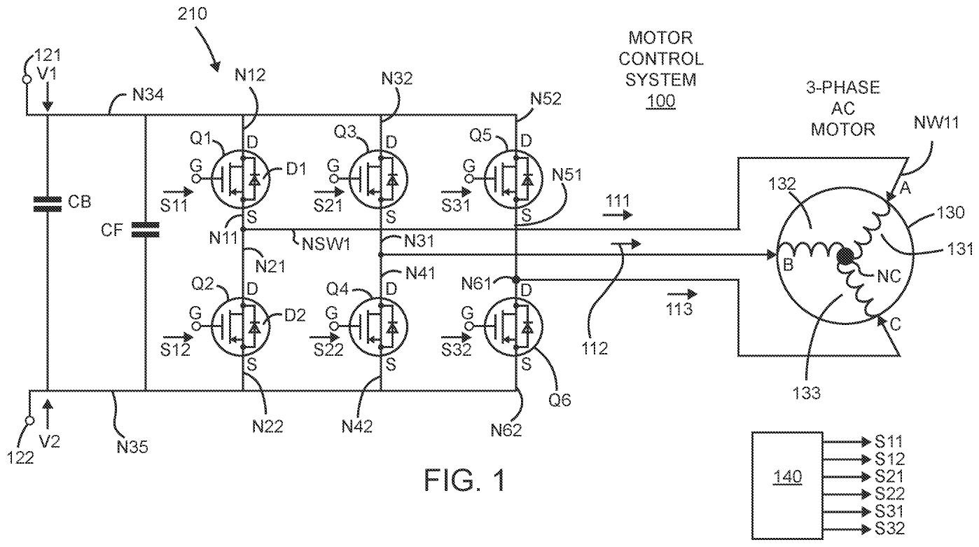

Now, more specifically, FIG. 1 is an example diagram illustrating a motor driver circuit as discussed herein.

In general, FIG. 1 is an example block diagram of electronic circuitry associated with a motor control system 100. In this example, the current (such as 111, 112, and 113) through the respective windings 131, 132, and 133 of the motor 130 is controlled by controller 140 and corresponding winding driver circuitry 210 and switches such as a 3-phase inverter with MOSFET (Metal Oxide Semiconductor Field Effect Transistor), IGBT (Insulated Gate Bipolar Transistor), GaN (Gallium Nitride) transistors, etc., as switching devices. Each of the windings is electrically connected to each other at the common node NC.

If desired, the controller 140 can be configured to monitor a magnitude of the respective current through each of the windings of the motor 130 and control such magnitudes of current to precise values.

As further shown, in this example, the bulk capacitor bank CB (such as providing slow current output response) is connected between the first voltage source 121 providing voltage V1 (such as a DC voltage) and the second voltage V2 (such as a DC voltage). The fast capacitor CF (such as providing fast current output response) is connected between the node N34 (first voltage V1) and the node N35 (second voltage V2).

Accordingly, each of the winding driver circuits is connected in series between the first voltage V1 and the second voltage V2.

More specifically, the switch Q1 (a.k.a., high side switch circuitry such as one or more switches) and switch Q2 (a.k.a., low side switch circuitry such as one or more switches) are connected in series between the node N12 and the node N22. For example, the drain node D of the switch Q1 is directly coupled to receive the first voltage V1 from the voltage source 121; the source node S of the switch Q1 is directly coupled to the drain node D of the switch Q2 via the switch node NSW1; the source node S of the switch Q2 is directly coupled to the node N35 supplying second voltage V2. Accordingly, both the node N11 and the node N21 are directly connect to the switch node NSW1 to supply current 111 to the node NW11 of the corresponding winding 131.

The switch Q3 (high side switch circuitry) and switch Q4 (low side switch circuitry) are connected in series between the node N32 and the node N42. For example, the drain node D of the switch Q3 is directly coupled to receive the first voltage V1 (node 34) from the voltage source 121; the source node S of the switch Q3 is directly coupled to the drain node D of the switch Q4; the source node S of the switch Q4 is directly coupled to the node 35 to receive the second voltage V2. Accordingly, both the node N31 and the node N41 are directly connected to supply current 112 to the corresponding winding 132.

The switch Q5 (high side switch circuitry) and switch Q6 (low side switch circuitry) are connected in series between the node N52 and the node N62. For example, the drain node D of the switch Q5 is directly coupled to receive the first voltage V1 from the voltage source 121; the source node S of the switch Q5 is directly coupled to the drain node D of the switch Q6; the source node S of the switch Q6 is directly coupled to the node N35 to receive the second voltage V2. Accordingly, both the node N51 and the node N61 are directly connected to collectively supply current 113 to the corresponding winding 133.

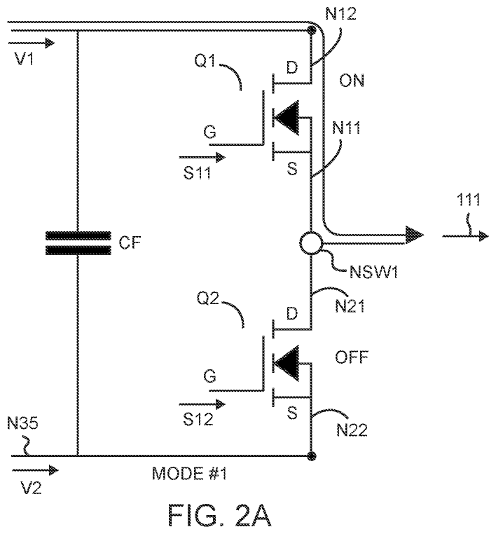

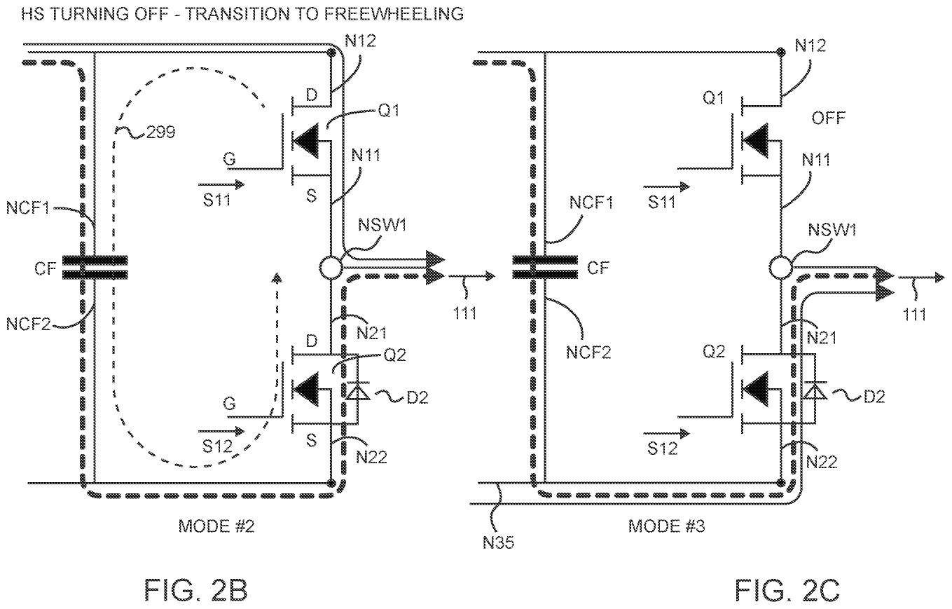

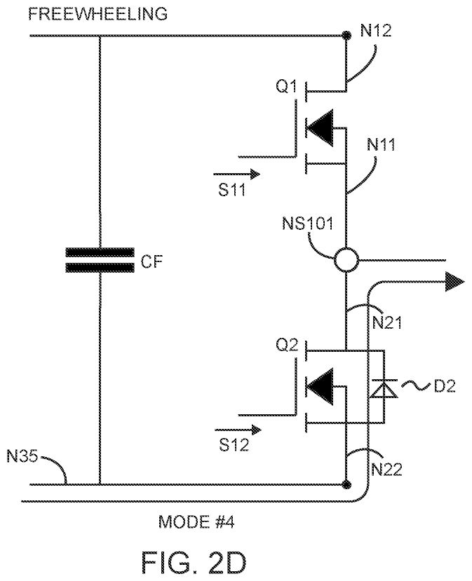

Different states of controlling the respective winding driver circuit such as including switch Q1 (such as high side switch circuitry) and switch Q2 (such as low side switch circuitry) are further shown in FIGS. 2A through 2D. Note that each of the pairs of switches (Q1-Q2, Q3-Q4, and Q5-Q6) in respective winding driver circuitry are operated in a similar manner to control respective current provided to the corresponding winding.

FIG. 2A is an example diagram illustrating operation of a respective winding driver in a first mode as discussed herein.

In this example, in the first operational mode (mode #1 such as between time T1 and time T2) as shown, the controller 140 generates the respective control signal S11 (such as to a high-voltage state) to drive the gate node G of the switch Q1, resulting in activation of the switch Q1 to an ON-state (very low impedance path between the node N12 and the node N11). Additionally, during the first operational mode #1, the controller 140 generates the respective control signal S12 (such as to a low-voltage state) to drive the gate node of the switch Q2, resulting in the deactivation of the switch Q2 to an OFF-state (such as a high impedance path between node N22 and node N21).

In such an instance, the low impedance path (switch Q1 set to an ON-state) between the node N12 and the node N11 results in the first voltage V1 (at node N12) providing energy (via current 111) to the winding 131.

In FIG. 2B is an example diagram illustrating a second mode of transitioning to deactivation of the high-side switch to operation of a low side switch in the freewheeling mode as discussed herein.

In this example, in the second operational mode (mode #2 such as around time T2) as shown, the controller 140 generates the respective control signal S11 such as to a low-voltage state to drive the gate node of the switch Q1, resulting in transition to deactivation of the switch Q1 to an OFF-state. Additionally, during the second operational mode #2 in FIG. 2B, the controller 140 generates the respective control signal S12 to drive the gate node of the switch Q2 to an OFF-state. During the transition to the freewheeling mode, the inherent diode D2 of the switch Q2 is forward biased.

In such an instance, the high impedance path (switch Q1 set to an OFF-state) between the node N12 and the node N11 results in the current to start flowing from the capacitor CF through the inherent diode D2 of the switch Q2, providing energy to the winding 131.

In mode #2 as shown in FIG. 2B, there is a commutation loop 299 such as based on the series combination of the circuit component capacitor CF, switch S12, and switch S11. More specifically, there is a short amount of time around time T2 during which both the switch Q1 is at least partially activated while the inherent diode D2 of switch Q2 is activated (a.k.a. forward biased), where the combination of first current from the node N12 through the switch Q1 to the node N11 and a second current from the capacitor CF through the inherent diode D2 to the node N21 is supplied to the corresponding current 111 to the winding 131. During the transition in mode #2, when the loop 299 acts as an inductor.

As discussed herein, it is desirable to fabricate the respective winding driver circuitry such that the physical size (cross-sectional area) of the commutation loop 299 (and corresponding parasitic inductance) is as small as possible to avoid overshooting of voltage to at corresponding switches (such as MOSFETs) within the transitioning commutation loop (half bridge).

FIG. 2C is an example diagram illustrating a third mode of transitioning from the activation of the high-side switch to operation in the freewheeling mode as discussed herein.

In this example, while switch Q1 and switch Q2 are both deactivated to an OFF-state, the first current from the node N12 through the switch Q1 to the node N11 decreases to zero. As previously discussed, the capacitor CF supplies first current through the inherent diode D2 of the switch Q2. Additionally, the node N35 such as associated with the second voltage (source 122) supplies second current through the diode D2 as well. The combination of both of these currents supplies the current 111 to the winding 131 during mode #3.

FIG. 2D is an example diagram illustrating a fourth mode of operating respective switch circuitry in a freewheeling mode as discussed herein.

While operating in the so-called freewheeling mode (mode #4), the second voltage V2 at node N35 supplies the corresponding current through the forward biased inherent diode D2, producing the current 111 supplied to the corresponding winding 131. In mode #4, no current is supplied by the capacitor CF through the forward biased diode D2. This completes the transition from the high side switch circuitry Q1 (mode #1) being turned on and operation of switch Q2 in the freewheeling mode (mode #4).

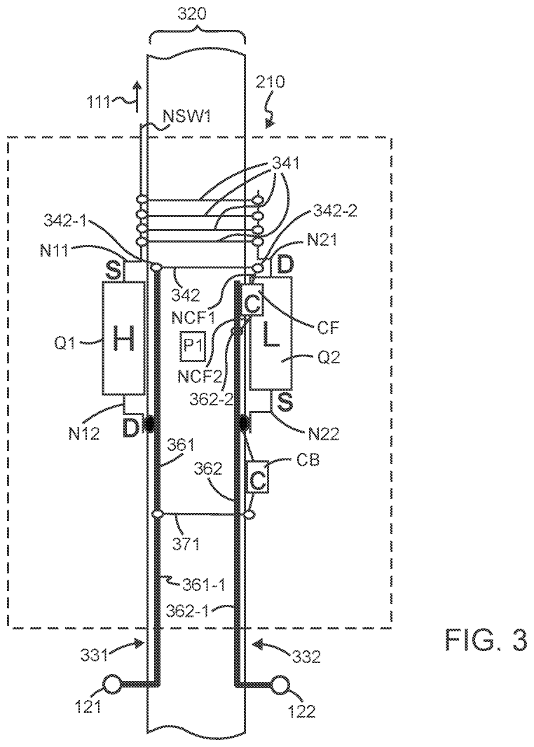

FIG. 3 is an example side view diagram of a respective motor winding driver circuit providing a reduced sized commutation loop as discussed herein.

In this example, the winding driver circuitry 210 (such as supplying current 111 to the winding 131) includes a substrate 320, switch Q1, switch Q2, bulk capacitor CB, and capacitor CF.

The electrically conductive path 361 conveys the voltage V1 from the voltage source 121 to the switch Q1 and corresponding electrically conductive path 342.

The electrically conductive path 362 conveys the second voltage V2 from the voltage source 122 to the multiple circuit components including the capacitor CB, switch Q2, and the capacitor CF.

As shown, the switch Q1 (such as a first switch component or first switch components connected in parallel) is affixed to the first surface 331 of the substrate 320. The switch Q2 (such as a second switch component or second switch components connected in parallel) is affixed to the second surface 332 of the substrate 320.

The first surface 331 (first face or first facing) is disposed on an opposite facing with respect to the second surface 332. The first switch Q1 can be disposed opposite the second switch Q2.

As previously discussed, the winding driver circuitry 210 can be configured to include the bulk capacitor bank CB. The capacitor bank CB can be configured to include one or more capacitors disposed on the surface 331 and/or the surface 332 of the substrate 320. Each of the capacitors associated with the capacitor bank CB may be connected between the first voltage (V1 or +Vdd) and the second voltage V2 (such as −Vss or ground).

In this example, the electrically conductive path 371 (one or more electrically conductive path through the substrate 320) provides connectivity of the capacitor bank CB between the electrically conductive path 361 and the electrically conductive path 362. Further, as previously discussed, the capacitor bank CB (providing low speed response) is disposed in parallel with the capacitor CF (providing high speed response for a short duration).

In one example, at least a portion of the substrate 320 is disposed between the first switch Q1 and the second switch Q2, although it is not necessary that the switch Q1 and switch Q2 be disposed directly opposite each other to create a reduced commutation loop 299 (inductive loop) as discussed herein.

As further shown, the one or more circuit paths 341 (such as fabricated from metal or other electrically conductive material) such as passing through the substrate 320 provide electrical connectivity between the node N11 of the first switch Q1 and the node N21 of the switch Q2.

As further shown, the switch Q1 and the switch Q2 are connected in series via a first series circuit path (including the one or more circuit paths 341) from the source node S (a.k.a., node N11) of switch Q1 to the drain node D (a.k.a., node N21) of switch Q2.

Note that each of the electrically conductive paths as discussed herein can be configured from metal or other suitable electrically conductive material and can be any suitable shape or size.

Yet further, winding driver circuitry 210 can be configured to include a respective electrically conductive path 361 extending from at least the node 361-1 to the node 342-1. Note that all or a portion of the electrically conductive path 361 may reside on the respective surface 331 of the substrate 320. All or a portion of the electrically conductive path 361 may reside internal to the substrate 320 such as when the substrate 320 is a multilayer circuit board.

Winding driver circuitry 210 can be configured to include a respective electrically conductive path 362 extending from the node 362-1 to the node 362-2. Note that all or a portion of the electrically conductive path 362 may reside on the respective surface 332 of the substrate 320. All or a portion of the electrically conductive path 362 may reside internal to the substrate 320 such as when the substrate 320 is a multilayer circuit board.

The node 361-1 of the electrically conductive path 361 is directly connected to receive the first voltage V1 from the first voltage source 121. The electrically conductive path 361 conveys the first voltage V1 to the drain node D (a.k.a., node N12) of the switch Q1. The electrically conductive path 361 also conveys the first voltage V1 to the node 342-1. The one or more electrically conductive paths 342 through the substrate 320 convey the received first voltage V1 at node 342-1 to the node 342-2.

The series circuit path between the node N12 of the switch Q1 and the node N22 of the switch Q2 further includes a series connection of: i) the capacitor CF connected between the node 342-2 and the node 362-2, and ii) a portion of the electrically conductive path 362 extending between the node 362-2 and the node N22 of the switch Q2.

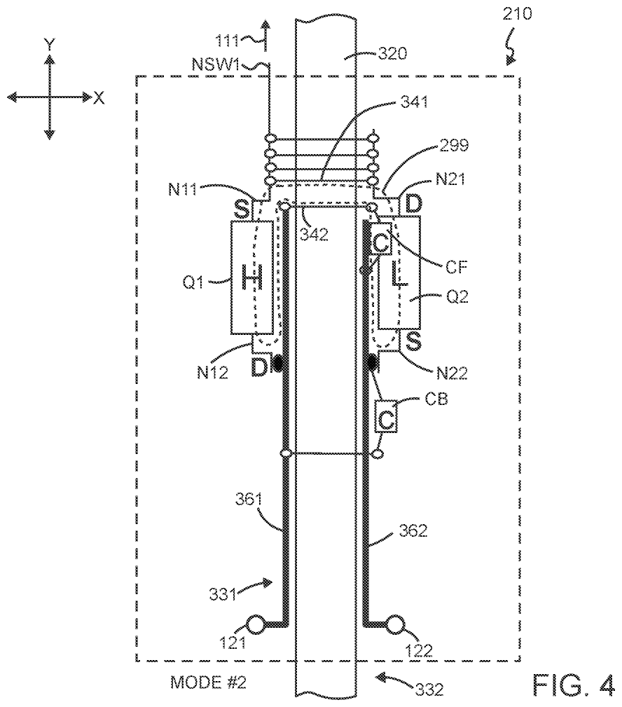

As further shown in FIG. 4, an inductive circuit loop (a.k.a., commutation loop 299) is formed via a series combination of: i) the first circuit path (such as connectivity between the source node of switch Q1 to the drain node of switch Q2 including the electrically conductive path 341 through the substrate 320), ii) drain node to source node through switch Q2, iii) the second circuit path (electrically conductive path including the capacitor CF disposed between the node N22 and node N12 including a portion of the electrically conductive path 362, electrically conductive path 342 and portion of the electrically conductive path 361), and iv) drain node to source node of the switch Q1.

In this example, during temporary condition mode #2 (see also FIG. 2B), the inductive circuit loop (299) exists based on simultaneous activation of both the first switch Q1 (such as supporting flow of first current from the node N12 to the node N11 and the second switch Q2 (such as inherent diode D2 in conduction mode or forward bias mode) supporting flow of second current from the node NCF2 to the node N21).

Accordingly, a first circuit path of the winding driver circuitry 210 is connected between a first node(S) of the first switch Q1 and a first node (D) of the second switch Q2. A second circuit path is connected between a second node (D) of the first switch Q1 and a second node(S) of the second switch Q2, the second circuit path including the capacitor CF. A first portion of the second circuit path such as a portion of the electrically conductive path 361 between node N12 and node 342-1 is disposed between a first portion P1 of the substrate 320 and the switch Q1. A second portion of the second circuit path such as a portion of the electrically conductive path 362 between node N22 and the node 362-2 is disposed between the portion P1 of the substrate 320 and the switch Q2.

Further, as previously discussed with respect to FIG. 2B, the controller 140 can be configured to control switching operation of the first switch Q1 and the second switch Q2 to control an overall flow of current 111 from the node NSW1 such as connected to the first circuit path (electrically conductive path between the node(S) of the switch Q1 through the one or more electrically conductive paths 341 to the node (D) of the switch Q2).

In this example, it may be desirable to dispose the capacitor CF nearer the node N21 (the drain node) of the switch Q2 than the second node N22 (such as source node) of the switch Q2.

Note further that the capacitor CF also may be disposed on the surface 331 of the substrate 320 instead of the surface 332. In such an instance, it may be desirable to dispose the capacitor CF nearer the first node N11 (the source node) of the switch Q1 than the second node N12 (such as drain node) of the switch Q1.

Yet further, it is noted that a first portion of the second circuit path (such as electrically conductive path 361 in combination with the circuit path 342) is operative to convey a first voltage V1 such as the first voltage to a first node NCF1 of the capacitor CF and a node N12 of the switch Q1. A second portion of the second circuit path (such as between node 362-1 and node 362-2) is operative to convey a second voltage V2 (second voltage or ground voltage) to a second node NCF2 of the capacitor CF and a second node N22 of the switch Q2. As previously discussed, the second voltage V2 made by the electrically conductive path 362 is a second voltage with respect to the first voltage V1. The controller 140 controls switching of the switch Q1 and the switch Q2 to convert the first voltage V1 into the output current 111 supplied to the corresponding winding 131.

Still further, it is noted that a first portion (such as a portion of the electrically conductive path 361) of the second circuit path as discussed herein can be configured to extend adjacent to the first switch Q1. For example, the portion of the electrically conductive path 361 between the node N12 and the node 342-1 is disposed adjacent to the switch Q1. A second portion of the second circuit path as discussed herein can be configured to extend adjacent to the switch Q2. For example, the portion of the electrically conductive path 362 between the node N22 and the node 362-2 is disposed adjacent to the switch Q2. As previously discussed, a portion such as portion P1 of the substrate 320 may be disposed between the first portion of the second circuit path and the second portion of the second circuit path.

Thus, the second circuit path as discussed herein may include a first portion, a second portion, and a third portion. The first portion of the second circuit path such as electrically conductive path 361 extends from node N12 of the first switch Q1 to the electrically conductive path 342 (i.e., a second portion of the second circuit path). The second portion of the second circuit path such as electrically conductive path 342 extends from the first surface 331 through the substrate 320 to the second surface 332 of the substrate 320 to the third portion (such as combination of capacitor CF and portion of the electrically conductive path 362 adjacent to the switch Q2). As previously discussed, the third portion of the second circuit path can be configured to extend on or beneath the second surface 332 from the second portion (such as the electrically conductive path 342) through the capacitor CF and the portion of the electrically conductive path 362 to the node N22 of the switch Q2.

Additionally, as shown in FIG. 3, the first portion (such as portion of the electrically conductive path 361) of the second circuit path as discussed herein may be disposed between the substrate 320 and the switch Q1. The third portion of the second circuit path (such as the electrically conductive path 362 between the node 362-2 and the node N22) may be disposed between the substrate 320 and the switch Q2.

FIG. 4 is an example diagram illustrating reduced cross-section area of a commutation loop as discussed herein.

Strategic placement of the different circuit components (such as the switch Q1, switch Q2, electrically conductive path 361, electrically conductive path 362, electrically conductive path 341, and electrically conductive path 342) as discussed herein helps to reduce the cross-sectional area of the commutation loop 299. As previously as discussed, the smaller sized commutation loop (inductive loop) is desirable to reduce transient voltage spikes with respect to the current 111 during transition from the switch Q1 turning on to off (and off to on) to operation of the switch Q2 in the freewheeling mode.

More specifically, placement of the electrically conductive path 342 near the electrically conductive path 341 as shown reduces a cross-section area of the commutation loop 299 in the X-Y plane. Placement of the portion of the electrically conductive path 361 between the node N12 and the node 342-1 very near the switch Q1 reduces a cross-section area of the commutation loop 299 in the X-Y plane. Placement of the portion of the electrically conductive path 362 between the node N22 and the node 362-2 very near the switch Q2 reduces a cross-section area of the commutation loop 299 in the X-Y plane.

Yet further, as previously discussed, the issue associated with the commutation loop 299 is the temporary mode #2 that occurs between mode #1 and mode #4.

More specifically, as previously discussed, the controller 140 as discussed herein controls the respective switches Q1 and Q2 resulting in mode #2 as a temporary condition occurring between the switching transition between mode #1 and mode #4. In other words, the mode #1 (see FIG. 2A) includes the controller 140 activating the switch Q1 to an ON-state while the switch Q2 is deactivated to an OFF-state. The mode #3 (see FIG. 2C) and mode #4 (see FIG. 2D) include the controller 140 causing deactivation of the switch Q1 to an OFF-state and operation of the switch Q2 in the freewheeling mode where current flows through the inherent diode D2 of the switch Q2 to produce the current 111. After the complete transition, operation in the mode #4 includes the current 111 provided solely from the second voltage V2 through the diode D2 without any current through the capacitor CF. Accordingly, the temporary condition (commutation loop 299 in mode #2) occurs between mode #1 and mode #3 and mode #4.

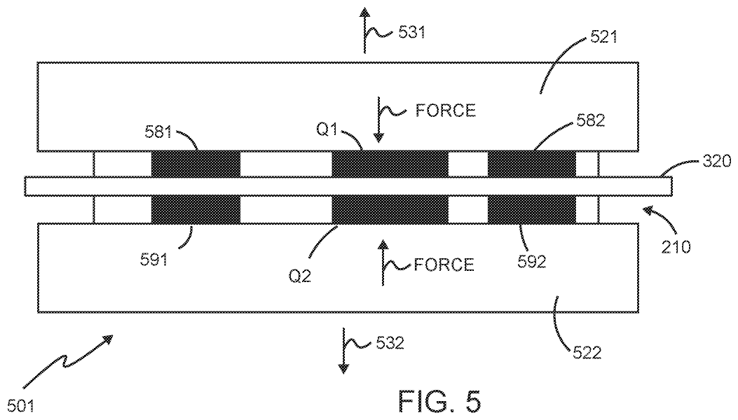

FIG. 5 is an example side view diagram illustrating an assembly including winding driver circuitry disposed between multiple heatsinks as discussed herein.

In this example, the assembly 501 includes the winding driver circuitry 210 disposed between multiple heatsinks to convey heat away from the respective switches Q1 and Q2.

More specifically, the winding driver circuitry 210 can be configured to include a first heat sink 521 spaced apart from the substrate 320 via the spacer 581 and the spacer 582. The winding driver circuitry 210 can be configured to include a second heatsink 522 spaced apart from the substrate 320 via the spacer 591 and the spacer 592.

The heatsink 521 can be configured to directly contact the switch Q1 or heatsink material can be disposed between the switch Q1 and the heatsink 521 to convey heat from the switch Q1 in the direction 531 away from the switch Q1.

As further shown, the heatsink 522 can be configured to directly contact the switch Q2 or heatsink material can be disposed between the switch Q2 and the heatsink 522 to convey heat from the switch Q2 in the direction 532 away from the switch Q2.

Accordingly, examples herein include a first heatsink 521 in thermal contact with the switch Q1 and a second heatsink 522 in thermal contact with the switch Q2. The assembly such as winding driver circuitry 210 may be disposed between the first heatsink 521 and the second heatsink 522.

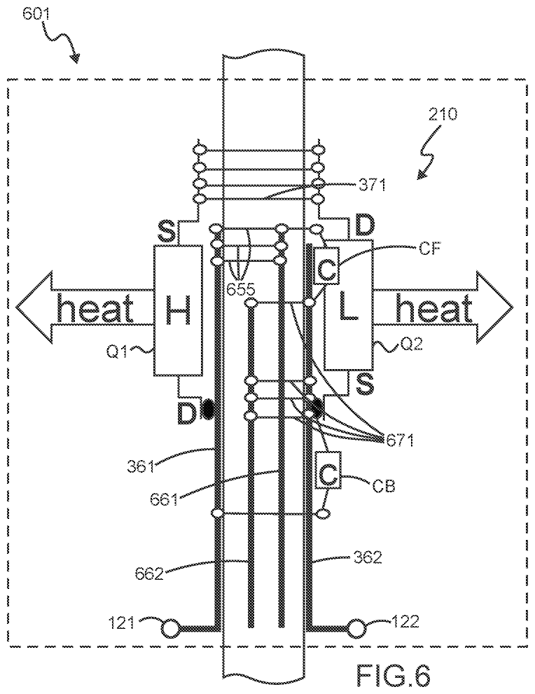

FIG. 6 is an example diagram illustrating implementation of a winding driver circuit including a first switch and a second switch disposed on opposite surfaces of a circuit board substrate as discussed herein.

In one example, the assembly 601 includes the winding driver circuitry 210 as well as additional electrically conductive paths (such as metal traces, metal layers of material, etc.,) disposed in one or more layers of the substrate 320.

More specifically, the winding driver circuitry 210 of the assembly 601 can be configured to include electrically conductive path 661 and electrically conductive path 662 (such as each electrically conductive path disposed in between the respective insulation layers of the substrate 320).

As shown in this example, the electrically conductive path 661 is separated from the electrically conductive path 662 via first insulation material (such as layer) in the substrate 320; the electrically conductive path 661 is separated from the electrically conductive path 362 via second insulation material (such as layer) in the substrate 320. The electrically conductive path 661 is connected to the first voltage source 121 and the electrically conductive path 361 via the electrically conductive paths 655. The combination of the electrically conductive path 361 and the electrically conductive path 661 and the electrically conductive path 6 and 55 conveys the corresponding first voltage V1 to the capacitor CF.

The electrically conductive paths 671 connects the electrically conductive path 662 to the electrically conductive path 362. The combination of the electrically conductive path 362, electrically conductive path 662, and the electrically conductive path 671 convey the voltage V2 from the voltage source 122 to the capacitor CF.

The benefit of including the electrically conductive path 661 in addition to the electrically conductive path 361 is the increased amount of current supplied to the node NCF1 of the capacitor CF. In other words, the combination of the electrically conductive path 361 and the electrically conductive path 661 provide a lower resistance path from the first voltage source 121 to the capacitor CF.

Additionally, as previously discussed, the electrically conductive path 662 is separated from the electrically conductive path 361 via third insulation material (such as layer) in the substrate 320; the electrically conductive path 662 is separated from the electrically conductive path 661 via fourth insulation material (such as layer) in the substrate 320. The electrically conductive path 662 is connected to the second voltage V2; the electrically conductive path 662 conveys the corresponding second voltage V2 to the electrically conductive paths 671. The benefit of including the electrically conductive path 662 in addition to the electrically conductive path 362 is the lower resistance path from the voltage source 122 to the capacitor CF. In other words, the combination of the electrically conductive path 362 and the electrically conductive path 662 provide a lower resistance path from the voltage source 122 to the node NCF2 of the capacitor CF.

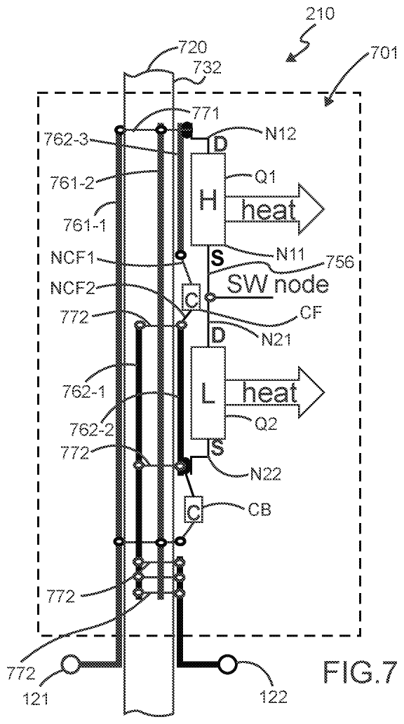

FIG. 7 is an example diagram illustrating implementation of a winding driver circuit including multiple switches disposed on the same surface of a circuit board substrate as discussed herein.

In this example, the assembly 701 can be configured to include substrate 720, capacitor CF, capacitor CB, switch Q1, and switch Q2.

Both the switch Q1 and the switch Q2 are affixed to the surface 732. For example, the first switch Q1 is coupled to the surface 732 of the substrate 720. The switch Q2 is coupled to the surface 732 of the substrate 720. The first switch Q1 and the second switch Q2 are connected in series via a first circuit path (electrically conductive path 756) connecting a first node N11 of the first switch Q1 to a first node N12 of the second switch Q2.

As further shown, the capacitor CF is disposed in series in a second circuit path extending from a second node N12 of the first switch Q1 to a second node N22 of the switch Q2. The second series circuit path may include the electrically conductive path 762-3 connecting the node N12 of switch Q1 to the node NCF1 of the capacitor CF. The electrically conductive path 762-2 provides connectivity between the node NCF2 of the capacitor CF and the node N22 of the switch Q2.

The configuration of the assembly 701 such as based on the first circuit path, the second circuit path, and the switches Q1 and Q2 provides a small cross-section associated with the corresponding loop 299.

Note further that at least a first portion (such as a portion of the electrically conductive path 762-3) of the second circuit path can be configured to reside between the switch Q1 and the substrate 720. At least a second portion (such as a portion of the electrically conductive path 762-2) of the second circuit path can be configured to reside between the second switch Q2 and the substrate 720.

Yet further, as previously discussed, a series combination of the first circuit path, the first switch Q1, the second circuit path, and the second switch Q2 create an inductive circuit loop (commutation loop 299) of small cross-section. The configuration of the winding driver circuitry 210 and physical placement of the components such as the switch Q1, switch Q2, capacitor CF, and interconnection circuitry in the assembly 701 reduces a corresponding cross-sectional region associated with the commutation loop 299.

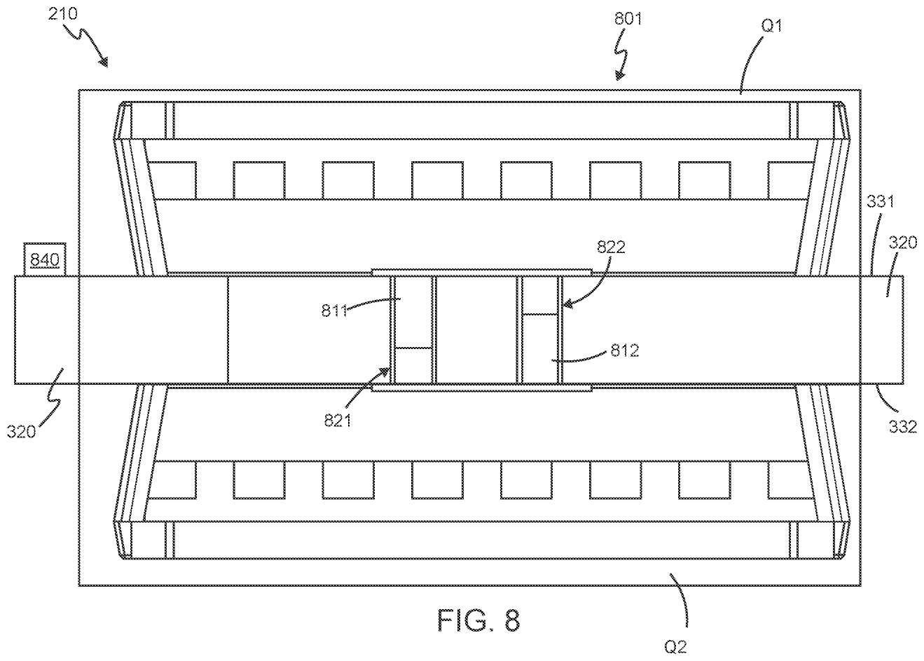

FIG. 8 is an example side view diagram of an assembly including implementation of multiple temperature sensor devices to monitor respective temperatures of switches in a winding driver circuit as discussed herein.

Note that the winding driver circuitry 210 can be implemented in the assembly 801 and can be configured to include multiple temperature sensors to monitor a respective temperature of each of the switches Q1 and Q2.

For example, as shown in the assembly 801 of FIG. 8, the substrate 320 can be configured to include a first cavity 821 and a second cavity 822 in the substrate 320. The temperature sensor 811 resides in the cavity 821 to monitor the respective temperature of the switch Q1. In a similar manner, the temperature sensor 812 resides in the cavity 822 to monitor the respective temperature of the switch Q2.

In one example, the assembly 801 includes the monitor circuit 840 to monitor a respective voltage across or current through each of the temperature sensors 811 and 812 to determine the temperature of the respective switches Q1 and Q2.

Accordingly, a first temperature sensor 811 can be disposed in a first cavity 821 of the substrate 320 between the first switch Q1 and the switch Q2. The first temperature sensor 811 (such as flush with the surface 331) can be in contact with the bottom surface of the switch Q1 to measure a temperature of the first switch Q2.

A second temperature sensor 812 (such as flush with surface 332) can be disposed in a second cavity 822 of the substrate 320 between the first switch Q1 and the second switch Q2. The second temperature sensor 812 can be in contact with the bottom surface of the switch Q2 to measure the temperature of the second switch Q2.

As previously discussed, the switch Q1 can be affixed to the first surface 331 of the substrate 320. The switch Q2 can be affixed to the second surface 332 of the substrate 320. To measure the temperature of the switch Q1, the temperature sensor 811 can be in contact with the switch Q1 and spaced apart from the switch Q2.

As previously discussed, the temperature sensors as discussed herein can be implemented in any suitable manner. In one example, the monitor circuit 840 or other suitable entity can be configured to drive a constant current through each of the temperature sensors. The monitor circuit 840 can be configured to further monitor one or more parameters (such as voltage, current, resistance, etc.) associated with each of the temperature sensors to determine the corresponding temperature of each of the switches.

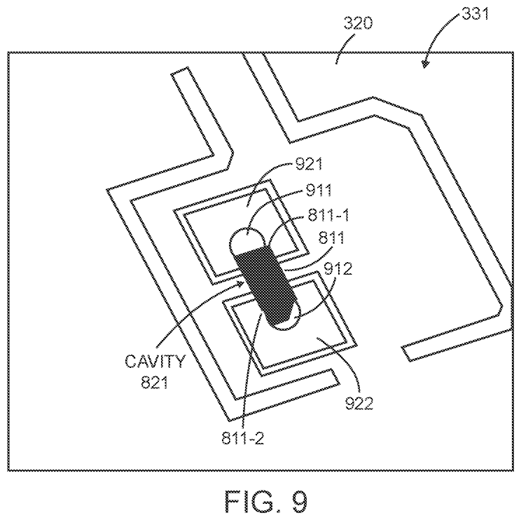

FIG. 9 is an example 3-D diagram illustrating implementation of a respective temperature sensor and cavity of a circuit board as discussed herein.

As shown in this example, the surface 331 of the substrate 320 may include surface pad 921 and surface pad 922 such as fabricated from metal or other suitable material. Additionally, the cavity 821 can be configured to include partial via 911 (such as coating of metal) present in one end of the cavity 821 as well as partial via 912 (such as coating of metal) present in the other end of the cavity 821.

The partial via 911 disposed in the cavity 821 and corresponding surface pad 921 is basically a first metal contact element; the partial via 912 disposed in the cavity 821 and corresponding surface pad 922 is basically a second metal contact element.

The first temperature sensor 811 (such as a thermistor, RTD, etc.,) includes a first node 811-1 and a second node 811-2. When inserted into the respective cavity 821, the first node 811-1 contacts the partial via 911 and is in electrical contact with the surface pad 921; the second node 811-2 contacts the partial via 912 and is in electrical contact with the surface pad 922. In a manner as previously discussed, the monitor circuit 840 or other suitable entity can be configured to monitor an attribute such as a voltage across or other parameter associated with the temperature sensor 811 to determine a respective temperature of the switch Q1.

Further, as previously discussed, the switch Q1 is affixed to the corresponding surface 331 of the substrate 320. The heat emanating from the switch Q1 is sensed by the temperature sensor 811.

In a further example, a current source can be configured to supply a fixed amount of current through the temperature sensor 811. In one example, the controller 140 can be configured to receive input from the monitor circuit 840, where the monitor circuit 840 monitors a magnitude of a voltage across node 811-1 and node 811-2 of the temperature sensor to derive a temperature sensor value indicative of the magnitude of temperature associated with the switch Q1.

Note again that techniques herein are well suited for use in circuit assembly applications such as those providing current to one or more windings of a respective motor. However, it should be noted that the disclosure of matter herein is not limited to use in such applications and that the techniques discussed herein are well suited for other applications as well.

While this invention has been particularly shown and described with references to preferred aspects thereof, it will be understood by those skilled in the art that various changes in form and details may be made therein without departing from the spirit and scope of the present application as defined by the appended claims. Such variations are intended to be covered by the scope of this present application. As such, the foregoing description in the present disclosure is not intended to be limiting. Rather, any limitations to the invention are presented in the following claims.

1. An apparatus comprising:
a substrate;
a first switch affixed to a first surface of the substrate;
a second switch affixed to a second surface of the substrate, the first switch and the second switch connected in series via a first circuit path extending through the substrate; and
a capacitor disposed in series in a second circuit path extending through the substrate, the first switch and the second switch connected in series via the second circuit path.

2. The apparatus as in claim 1, wherein a series combination of the first circuit path, the first switch, the second circuit path, and the second switch create an inductive circuit loop.

3. The apparatus as in claim 1, wherein the first circuit path is connected between a first node of the first switch and a first node of the second switch; and
wherein the second circuit path is connected between a second node of the first switch and a second node of the second switch.

4. The apparatus as in claim 3, wherein a first portion of the second circuit path is disposed between a first portion of the substrate and the first switch; and
wherein a second portion of the second circuit path is disposed between the first portion of the substrate and the second switch.

5. The apparatus as in claim 4, wherein the first node of the first switch is a source node; and
wherein the first node of the second switch is a drain node.

6. The apparatus as in claim 5 further comprising:
a controller operative to control switching operation of the first switch and the second switch, the controlled switching operation operative to control a flow of current from the first circuit path through a winding of a motor.

7. The apparatus as in claim 3, wherein the capacitor is disposed nearer the first node of the first switch than the second node of the first switch.

8. The apparatus as in claim 1 further comprising:
a first heat sink in contact with the first switch;
a second heat sink in contact with the second switch; and
wherein an assembly of the first switch, the substrate, and the second switch is disposed between the first heat sink and the second heat sink.

9. The apparatus as in claim 1 further comprising:
a first temperature sensor disposed in a first cavity of the substrate between the first switch and the second switch, the first temperature sensor operative to measure a temperature of the first switch; and
a second temperature sensor disposed in a second cavity of the substrate between the first switch and the second switch, the second temperature sensor operative to measure a temperature of the second switch.

10. The apparatus as in claim 1, wherein the first circuit path provides connectivity between a first node of the first switch and a first node of the second switch;
wherein a first portion of the second circuit path is operative to convey a first voltage to a first node of the capacitor and a second node of the first switch; and
wherein a second portion of the second circuit path is operative to convey a second voltage to a second node of the capacitor and a second node of the second switch, the second voltage being a second voltage with respect to the first voltage.

11. The apparatus as in claim 10 further comprising:
a controller operative to control operation of the first switch and the second switch to produce an output current outputted from the first circuit path to a first winding of a motor.

12. The apparatus as in claim 1, wherein the first circuit path provides connectivity between a first node of the first switch and a first node of the second switch;
wherein the second circuit path includes a first portion, a second portion, and a third portion;
wherein the first portion of the second circuit path extends from a second node of the first switch to the second portion of the second circuit path;
wherein the second portion of the second circuit path extends from the first surface through the substrate to the second surface of the substrate to the third portion; and
wherein the third portion of the second circuit path extends on the second surface from the second portion to the second node of the second switch.

13. The apparatus as in claim 12, wherein the first portion of the second circuit path is disposed between the substrate and the first switch; and
wherein the third portion of the second circuit path is disposed between the substrate and the second switch.

14. The apparatus as in claim 1, wherein the substrate is disposed between the first switch and the second switch.

15. The apparatus as in claim 1, wherein a first portion of the second circuit path extends adjacent to the first switch;
wherein a second portion of the second circuit path extends adjacent to the second switch; and
wherein at least a portion of the substrate is disposed between the first portion of the second circuit path and the second portion of the second circuit path.

16. The apparatus as in claim 1, wherein the second circuit path is operative to support conveyance of temporary current flow during a transition of switching between a first mode and a second mode;
wherein the first mode includes activation of the first switch and deactivation of the second switch; and
wherein the second mode includes deactivation of the first switch and a diode in the second switch operating in a forward bias state.

17. An apparatus comprising
a substrate;
a first switch affixed to a first surface of the substrate;
a second switch affixed to the first surface of the substrate, the first switch and the second switch connected in series via a first circuit path connecting a first node of the first switch to a first node of the second switch; and
a capacitor disposed in series in a second circuit path extending from a second node of the first switch to a second node of the second switch.

18. The apparatus as in claim 17, wherein at least a first portion of the second circuit path resides between the first switch and the substrate; and
wherein at least a second portion of the second circuit path resides between the second switch and the substrate.

19. The apparatus as in claim 18, wherein a series combination of the first circuit path, the first switch, the second circuit path, and the second switch create an inductive circuit loop depending upon operational states of the first switch and the second switch.

20. An apparatus comprising:
a substrate;
a first switch affixed to the substrate; and
a first temperature sensor disposed in a first cavity of the substrate, the first temperature sensor operative to measure a temperature of the first switch.
